(19) United States
(12) Patent Application Publication
(10) Pub. No.: US 2026/0040888 A1
(43) Pub. Date: Feb. 5, 2026

(54) SUBSTRATE TRANSFER ROBOT ASSEMBLIES, SUBSTRATE PROCESSING SYSTEMS, METHODS OF MAKING SUBSTRATE PROCESSING SYSTEMS, AND METHODS OF TRANSFERRING SUBSTRATES IN SUBSTRATE PROCESSING SYSTEMS

(71) Applicant: ASM IP Holding B.V., Almere (NL)

(72) Inventor: Samer Banna, Phoenix, AZ (US)

(21) Appl. No.: 19/281,847

(22) Filed: Jul. 28, 2025

Related U.S. Application Data
(60) Provisional application No. 63/677,904, filed on Jul. 31, 2024.

(51) Int. Cl. H01L 21/687; B25J 9/04; B25J 11/00; H01L 21/67

(52) U.S. Cl. CPC H01L 21/68707; B25J 9/043; B25J 11/0095; H01L 21/67167

(57) ABSTRACT

A substrate transfer robot assembly includes a tower, a first arm with a first end effector, and a second arm with a second end effector and a third end effector. The tower defines a tower axis, the first arm and the second arm extend radially outward from the tower, the first end effector is coupled to the tower by the first arm, and the second end effector and a third end effector are coupled to the tower by the second arm. The first end effector is supported by the first arm for translation from the tower radially relative to the tower axis, and the second end effector and the third end effector are supported by the second arm for translation from the tower radially relative to the tower axis. Substrate processing systems, methods of making substrate processing systems, and substrate transfer methods are also described.

### CROSS-REFERENCE TO RELATED APPLICATIONS

This application claims priority to and the benefits of U.S. Provisional Application No. 63/677,904, filed on Jul. 31, 2024, the contents of which is incorporated herein by reference in its entirety.

### FIELD OF INVENTION

The present disclosure generally relates to substrate handing, and more particularly to handling substrates in substrate processing systems using substrate transfer robot assemblies.

### BACKGROUND OF THE DISCLOSURE

A process of using a substrate processing apparatus includes a step of transporting a substrate from a Front Opening Unified Pod (FOUP) to a processing chamber via a substrate handling chamber and a load lock module using a robotic arm of a vacuum robot, or a step of transporting a substrate from a reaction chamber to another reaction chamber using a robotic arm. The robotic arm may be provided with an end effector for loading a substrate thereon and carrying the substrate from one chamber to another.

In conventional systems, vacuum robots may include one or more end effectors corresponding to the number of chambers included in the process module platform. For example, platforms having single chamber process modules typically include robots having single end effector. In that vein, platforms having dual chamber process modules or quad chamber process modules typically include two end effectors fixed relative to one another, or in a dual arm robot, two sets of end effectors (one set on each arm).

Such correspondence between the number of end effectors and the number of process module chambers may limit robot movement required for wafer transfer and further may limit the substrate transfer robot assembly to constrain throughput of the semiconductor processing system. For example, in platforms that may accommodate more than one type of processing chamber at one, including a single end effector may require greater number of movements (such as two or four) to transfer wafers in an out of a dual chamber module (DCM) or quad chamber module (QCM) compared to conventional moves (such as one or two) in traditional platforms. Thus, there is a need in the art for systems and methods to enable smooth and fast transfer of wafers between chambers in a platform system accommodating a plurality of processing modules wherein each processing module may include different number of process chambers from another processing module.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A substrate transfer robot assembly is provided. The substrate transfer robot assembly includes a tower, a first arm with a first end effector, and a second arm with a second end effector and a third end effector. The tower defines a tower axis, the first arm and the second arm extend radially outward from the tower, the first end effector is coupled to the tower by the first arm, and the second end effector and a third end effector are coupled to the tower by the second arm. The first end effector is supported by the first arm for translation from the tower radially relative to the tower axis, and the second end effector and the third end effector are supported by the second arm for translation from the tower radially relative to the tower axis.

In addition to one or more of the features described above, or as an alternative, further examples of the substrate transfer robot assembly may include that one of the first arm and the second is supported for pivotable movement relative to the tower and about the tower axis.

In addition to one or more of the features described above, or as an alternative, further examples of the substrate transfer robot assembly may include that one of the first arm and the second arm is fixed relative to the tower and about the tower axis.

In addition to one or more of the features described above, or as an alternative, further examples of the substrate transfer robot assembly may include that one of the first arm and the second arm is pivotably fixed relative to the tower about the tower axis.

In addition to one or more of the features described above, or as an alternative, further examples of the substrate transfer robot assembly may include that the first arm couples one and only one end effector to the tower. In further examples, or as an alternative, further examples of the substrate transfer robot assembly may include that the second arm couples only two end effectors to the tower.

In addition to one or more of the features described above, or as an alternative, further examples of the substrate transfer robot assembly may include the third end effector is fixed relative to the second end effector. The third end effector may be configured for translation in tandem with the second end effector radially from the tower and relative to the tower axis.

In addition to one or more of the features described above, or as an alternative, further examples of the substrate transfer robot assembly may include that one of the first arm and the second is supported for pivotable movement relative to the tower and about the tower axis, that the other of the first arm and the second arm is pivotably fixed relative to the tower and about the tower axis, that the first arm couples one and only one end effector to the tower, and that the third end effector is fixed relative to the second end effector and configured for translation in tandem with the second end effector radially from the tower and relative to the tower axis.

A substrate processing system is provided. The substrate processing system includes a substrate handling chamber, a substrate transfer robot assembly as described above, a first processing module and a second processing module, and a controller. The tower of the substrate transfer robot is supported the substrate handling chamber for rotation about the tower axis. The first processing module coupled to the substrate handling chamber, the second processing module coupled to the substrate handling chamber and configured to process a greater number of substrates than the first processing module, and the controller is operatively connected to the substrate transfer robot assembly and responsive to instructions recorded on a memory to transfer a single substrate into the first processing module using the first end effector and simultaneously transfer two substrates into the second processing module using the second end effector and the third end effector.

In addition to one or more of the features described above, or as an alternative, further examples of the substrate processing system may include that the first processing module is a single chamber module. The second processing module may be a dual chamber module or a quad chamber module.

In addition to one or more of the features described above, or as an alternative, further examples of the substrate processing system may include a third processing module. The third processing module may be coupled to the substrate handling chamber. The second processing module may be a dual chamber module. The third processing module may be a quad chamber module. The instructions may further cause the controller to simultaneously transfer two substrates into the third processing module using the second end effector and the third end effector.

In addition to one or more of the features described above, or as an alternative, further examples of the substrate processing system may include a singular gate valve, a first gate valve pair, and a second gate valve pair. The singular gate valve may couple the substrate transfer chamber to the first processing module. The first gate valve pair may couple the substrate transfer chamber to the second processing module. The second gate valve pair may couple the substrate transfer chamber to the third processing module.

In addition to one or more of the features described above, or as an alternative, further examples of the substrate processing system may include a fourth processing module. The further processing module may be a single chamber module and the instructions may further cause the controller to transfer a single substrate into the fourth processing module using the first end effector.

In addition to one or more of the features described above, or as an alternative, further examples of the substrate processing system may include a load lock module and one or more gate valve. The one or more gate valve may couple the substrate handling chamber to the load lock module.

In addition to one or more of the features described above, or as an alternative, further examples of the substrate processing system may include that the one or more gate valve is a plurality of gate valves. The instructions may further cause the controller to open only one of the plurality of gate valve to transfer a single wafer from the load lock module to the first process module. The instructions may further cause the controller to open two of the plurality of gate valves to transfer two wafers from the load lock module to the second process module using the second end effector and the third end effector.

A method of transferring wafers from a load lock module to a respective processing module is provided. The method includes providing a substrate transfer robot assembly having a first arm and a second arm, wherein the first arm comprises a first end effector, and wherein the second arm comprises a second end effector and a third end effector, coupling a first processing module to the substrate handling chamber, wherein the first processing module is a single chamber module, coupling a second processing module to the substrate handling chamber, wherein the second processing module is one of a dual chamber module and a quad chamber module, and controlling the substrate transfer robot assembly to transfer one substrate between the load lock module and the first processing module using the first arm, and further transfer a plurality of substrates simultaneously between the load lock module and the second processing module using the second arm.

In addition to one or more of the features described above, or as an alternative, further examples of the method may include coupling a third processing module to the substrate handling chamber, that the second processing module is a dual chamber module and the third processing module is a quad chamber module, and controlling the substrate transfer robot assembly to transfer a plurality of substrates simultaneously between the load lock module and the third processing module using the second arm.

In addition to one or more of the features described above, or as an alternative, further examples of the substrate processing system may include coupling a fourth processing module to the substrate handling chamber, wherein the fourth processing module is a single chamber module, and controlling the substrate transfer robot assembly to transfer a single substrate between the load lock module and the fourth processing module using the first arm.

In addition to one or more of the features described above, or as an alternative, further examples of the substrate processing system may include providing a rotatable tower comprised in the substrate transfer robot assembly wherein the second arm is translatable relative to the rotatable tower and wherein the first arm is rotatable relative to the second arm, and controlling the rotatable tower to transfer substrates between the load lock module and the first processing module independently of the movement of the second arm.

In addition to one or more of the features described above, or as an alternative, further examples of the substrate processing system may include controlling the substrate transfer robot assembly to transfer one substrate between the load lock module and the first processing module using the first arm includes transferring one and only substrate between the load lock module and the first processing module using a singular end effector coupled to the tower by the first arm.

In addition to one or more of the features described above, or as an alternative, further examples of the substrate processing system may include that controlling the substrate transfer robot assembly to controlling the substrate transfer robot assembly to transfer a plurality of substrates simultaneously between the load lock module and the second processing module using the second arm further comprises simultaneously transferring two wafers using a second end effector and a second end effector coupled to the tower by the second arm.

In addition to one or more of the features described above, or as an alternative, further examples of the substrate processing system may include that the third end effector is fixed relative to the second end effector, and that the two substrates each comprise a singular wafer.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates a top view of substrate processing system in accordance with exemplary embodiments of the disclosure;

FIG. 2 illustrates a top view of a dual arm robot of FIG. 1 in accordance with exemplary embodiments of the disclosure; and

FIG. 3 illustrates a flow diagram of a method for transferring wafers between a load lock module and a respective processing module such as the ones included in substrate processing system of FIG. 1 in accordance with exemplary embodiments of the disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be used in semiconductor processing systems employed to fabricate semiconductor devices, such as in semiconductor processing systems used to deposit material layers using chemical vapor deposition (CVD) and atomic layer deposition (ALD) techniques during the fabrication of logic and memory semiconductor devices, though the present disclosure is not limited to any particular type semiconductor processing system or to semiconductor processing systems in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

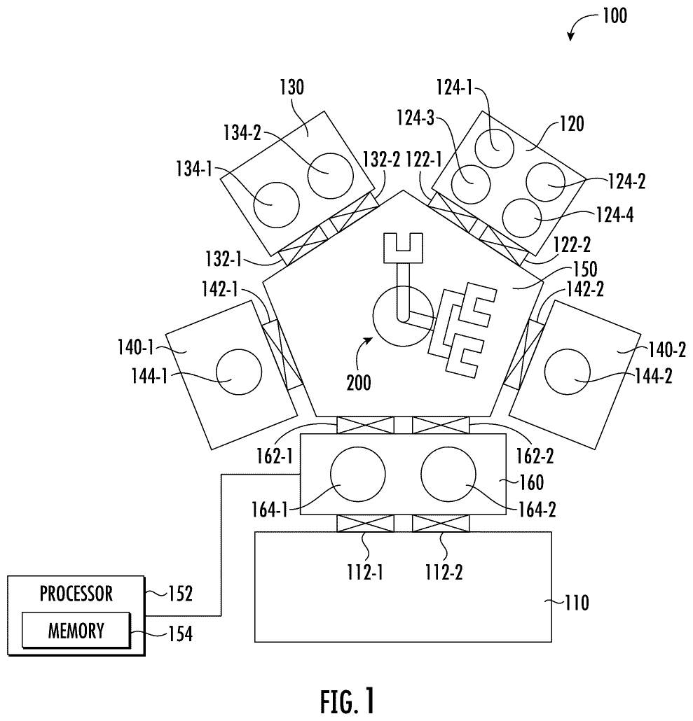

Referring to FIG. 1, a substrate processing system 100 is shown according to an example of the present disclosure. In the illustrated example the substrate processing system 100 includes an equipment front end module (EFEM) 110, a load lock module 160, a substrate handling chamber (SHC) 150, one or more processing modules (120, 130, 140) and a controller 152 including a memory 154. Generally, unprocessed wafers are accessed by the substrate processing system in FOUP. The EFEM 110 includes a front-end robot (not shown) that is configured to obtain wafers from the FOUP and readied to be transported to the load lock module 160. The transfer of wafers from load lock module to a processing module is handled by a substrate transfer robot assembly 200 in the substrate handling chamber 150. The substrate handling chamber 150 may be a vacuum chamber. Accordingly, substrate transfer robot assembly 200 operates in a vacuum environment. The interior of each of the processing modules (120, 130, 140) and the load lock module 160 may be isolated from the interior of the substrate handling chamber 150 by one or more gate valves 122, 132, 142, and 162.

In the example shown in FIG. 1, substrate processing system 100 includes a cluster-type platform with four process modules configured to deposit a material layer on a substrate using various deposition techniques (for example, atomic layer deposition (ALD)). This for illustration and description purposes only and is non-limiting. As will be appreciated by those of skill in the art in view of the present disclosure, substrate processing systems configured for other material layer deposition operations as well as semiconductor processing systems configured for processing operations other than material layer deposition can also benefit from the present disclosure.

In the example shown in FIG. 1, SHC 150 is coupled to four processing modules 120, 130, 140-1 and 140-2. Each of the processing modules 120, 130 and 140-1 and 140-2 are coupled to SHC 150 via one or more gate valves. As shown in FIG. 1, processing module 120 is coupled to SHC 150 via one or more gate valves 122-1 and 122-2. Further, processing module 130 is coupled to SHC 150 via one or more gate valves 132-1 and 132-2. Also, processing module 140-1 is coupled to SHC 150 via one or more gate valve(s) 142-1 and processing module 140-2 is coupled to SHC 150 via one or more gate valve(s) 142-2.

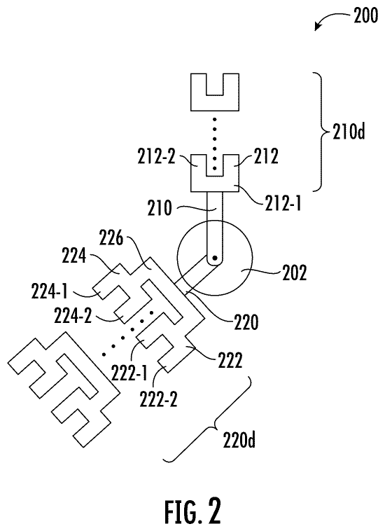

SHC 150 includes at least one substrate transfer robot assembly 200 (see FIG. 2). substrate transfer robot assembly 200 further includes a plurality of arms 210 and 220 that are used to move substrates into and out of the various processing modules 120, 130 and 140-1 and 140-2. In use, a gate valve (such as 122, 132, 142) is opened, and an end effector of robotic arm (210, 220) extends through the open gate valve to insert a substrate into or remove substrate from an interior chamber of the respective processing module (e.g. placing a substrate on or taking a substrate off one of the substrate supports 124, 134, 144). Once the robotic arm is retracted from processing module (120, 130, 140), the gate valve is closed, thereby sealing the processing module from the gate valve.

In exemplary embodiments, gate valve 142-1 (coupled to SHC 150 and processing module 140-1), gate valve 142-2 (coupled to SHC 150 and processing module 140-2), gate valve(s) 132-1 and 132-2 (coupled to SHC 150 and processing module 130), and gate valve(s) 122-1 and 122-2 (coupled to SHC 150 and processing module 150) have the same structure as each other and/or at least function in a manner similar to each other.

Substrate processing system 100 further includes load lock module 160 which is connected to a fifth facet (the one not connected to the processing module(s)) of SHC 150 by one or more load lock gate valves 162-1 and 162-2. In exemplary embodiments, gate valve(s) 112-1 and 112-2 have the same structure as gate valves 122, 132 and 142. In exemplary embodiments two gate valves 162-1 and 162-2 are used to couple load lock module 160 to SHC 150. In other exemplary embodiments, less than or more than two gate valves may be used. The load lock module includes one or more substrate holding components 164-1 and 164-2 for holding the substrate on the way into SHC 150 for further processing or on the way out of SHC 150 after processing is complete. The end effector of robotic arm(s) 210 or 220 moves through gate valve(s) 162-1 and/or 162-2 (when opened) to move substrate into the SHC 150 (for layer deposition and other processing) and out of SHC 150 (after processing is completed). Accordingly, load lock module—keep the substrates isolated from the environment of SHC 150 until the conditions (for example, temperature, pressure, content of atmosphere, etc.) within the SHC 150 are ready for the substrate(s) to be inserted.

The load lock module 160 is further coupled with an equipment front end module (EFEM) 110 via one or more additional gate valve(s) 112-1 and 112-2. In exemplary embodiments, gate valves 112-1 and 112-2 have the same structure as gate valve(s) 122, 132, 142, 162 as described above. EFEM 110 further includes a robot that moves the substrate from the FOUP into load lock module 160 (to eventually transport to processing chamber(s) 120, 130, 140-1 and/or 140-2 for layer deposition and other processing) and out of load lock module 160 (after processing is completed back to FOUP. In exemplary embodiments, at least four FOUPs are coupled to EFEM 110.

Accordingly, in substrate processing system 100 of FIG. 1, multiple processing modules 120, 130, 140-1 and 140-2 are coupled with a single SHC 150. These processing modules are rigidly attached to SHC 150 through gate valves 122, 132 and 142. Gate valves 122, 132 and 142-1 and 142-2 sealingly couple processing modules 120, 130, 140-1 and 140-2, respectively with SHC 150 and provide a window that may be selectively opened and closed (and sealed), and through which substrates can be transferred into and out of the respective processing module. Accordingly, in exemplary embodiments, EFEM 110, load lock chamber 160, SHC 150 and processing modules 120, 130, 140-1 and 140-2 can all have different environmental zones (e.g., temperature zones, pressure zones, etc.) but gate valve(s) 112, 122, 132, 142 and 162 remain sealed and do not allow the substrates to be passed from one chamber to another until the environmental zones between two chambers is equalized.

The platform system of substrate processing system 100 shown in FIG. 1 is configured to accommodate varying types of processing modules. For example, one or more of processing modules 120, 130 and 140-1 and 140-2 may be single chamber modules. In some examples, two of the processing modules may be single chamber modules (SCM) and two may be dual chamber modules (DCM). In some other examples, two of the processing modules may be SCM and two may be quad chamber modules (QCM). In further examples, each of the four process modules may be SCM's. Accordingly, various processing module combinations may be accommodated by substrate processing system 100.

In exemplary embodiments, processing modules 140-1 and 140-2 are single chamber modules. That is, modules 140-1 and 140-2 are able to accommodate a single process reactor and only one wafer may be processed in modules 140-1 and 140-2 at a time. Processing module 140-1 includes a substrate support 144-1 and processing module 140-2 includes a substrate support 144-2. Processing module 140-1 may be coupled to SHC 150 via one or more gate valve(s) 142-1. Similarly, processing module 140-2 may be coupled to SHC 150 via one or more gate valve(s) 142-2. An end effector of substrate transfer robot assembly 200 may extend through gate valve 142-1 and gate valve 142-2 to pick up or place substrates on substrate support 144-1 and substrate support 144-2 respectively.

In exemplary embodiments, processing module 130 is a dual chamber module (DCM). That is, processing module 130 is able to accommodate two process reactors and two wafers may be processed in processing module 130 simultaneously. Processing module 130 includes two substrate supports 134-1 and 134-2. In the example shown in FIG. 1, processing module 130 may be coupled to SHC via two gate valves 132-1 and 132-2. An end effector of robot 200 may extend through gate valves 132-1 and 132-2 to pick up or place substrates on supports 134-1 and 134-2 for processing.

In exemplary embodiments, processing module 140 is a quad chamber module (QCM). That is, processing module 140 is able to accommodate four process reactors and four wafers may be processed in processing module 140 simultaneously. Processing module 140 includes four substrate supports 144-1 144-2, 144-3 and 144-4. In the example shown in FIG. 1, processing module 140 may be coupled to SHC via two gate valves 142-1 and 142-2. An end effector of robot 200 may extend through gate valves 132-1 and 132-2 to pick up or place substrates on supports 144-1, 144-2, 144-3 and 144-4.

Referring now to FIG. 2, substrate transfer robot assembly 200 included in substrate processing system 100 is illustrated. In exemplary embodiments, substrate transfer robot assembly 200 includes a plurality of arms. In the example shown in FIG. 2, substrate transfer robot assembly 200 is a dual-arm having first arm 210 and second arm 220. In exemplary embodiments, first arm 210 may be connected to an end effector 212. End effector 212 is configured to support substrates thereon. End effector 212 further includes two fingers 212-1 and 212-2 protruding out at the end of the end effector 212. In the example shown in FIG. 2, arm 210 is attached to a single end effector 212. Thus, first arm 210 is configured to support a single wafer.

In exemplary embodiments, second arm 220 includes a fork shaped section 226 which is further connect to two end effectors 222 and 224. End effectors 222 and 224 are configured to support substrates thereon. As shown in FIG. 2, end effector 222 includes two fingers 222-1 and 222-2 protruding out at the end of end effector 222. Similarly, end effector 224 also includes two fingers 224-1 and 224-2 protruding out at the end of end effector 224. End effector 222 is fixed relative to end effector 224.

First arm 210 and second arm 220 may be connected to a rotatable tower 202 (and to each other). Accordingly, second arm 220 is rotatable relative to first arm 210 and vice versa. Movement of both first arm 210 and second arm 220 may be controlled by controlling actuator 202 via controller 152 (shown in FIG. 1). Further, controller 152 may include a scheduling module that is configured to transfer wafers in and out of processing modules 120, 130 and 140-1 and 140-2.

Because first arm 210 is configured to transfer a single wafer and second arm 220 is configured to transfer two wafers, robot 200 can enable transfer of wafers into and out of single chamber modules 140-1 and 140-2 independently of the movement of second arm 220. Similarly, robot 200 can also enable transfer of wafers into and out of processing module 130 (e.g., a DCM) or processing module 140 (e.g., a QCM) independently of the movement of first arm 210. Further, end effector 212 is translatable relative to second arm 220 and end effectors 222 and 224 are translatable relative to first arm 210. As further shown in FIG. 2, when a gate valve (such as valve 142-1, 142-2, 162-1) is open, arm 210 may move end effector 212 (up to a distance 210d) into a respective chamber (such as SCM 140-1, 140-2 or load lock module 160) to carry a single substrate into or out of the chamber. Similarly, when gate valves (such as valves 122-1 and 122-2, 132-1 and 132-2, and 162-1 and 162-2) are open, arm 220 may move end effectors 222 and 224 (up to a distance 220d) into a respective chamber (such as SCM 120, 130 or load lock module 160) to carry multiple substrates into or out of the chamber at one time.

Further, in exemplary embodiments, arm 210 is designed such that end effector 212 may be exchangeable and/or replaced with any other appropriate end effector (for example, end effector 212 may be swapped out and replaced with end effector such as 226 that include two fixed end effectors, which support two wafers at a time). In exemplary embodiments, arm 220 is designed such that fork 226 may be exchangeable and/or replaced with any other appropriate end effector (for example, end effector including end effectors 222 and 224 may be swapped out for a single end effector such as 212 that is configured to support a single wafer at a time). Thus, substrate transfer robot assembly 200 has scheduling flexibility and limits the likelihood that substrate transfer robot assembly 200 constrains platform throughput.

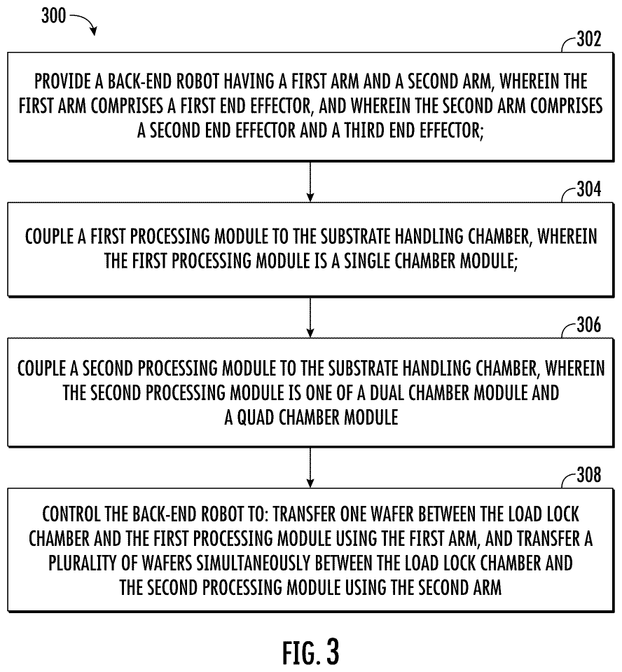

FIG. 3 illustrates a method of transferring wafers from a load lock module, such as load lock module 110 to a respective processing module (such as modules 120, 130, 140). Step 302 of method 300 includes providing a substrate transfer robot assembly having a first arm, such as first arm 210, and a second arm, such as second arm 220. The first arm includes a first end effector, such as end effector 212, and the second arm includes a second end effector, such as end effector 222 and a third end effector, such as end effector 224.

Step 304 of method 300 includes coupling a first processing module, such as processing module 140-1 to the substrate handling chamber, such as substrate handling chamber 150, wherein the first processing module is a single chamber module. Step 306 of method 300 includes coupling a second processing module, such as module (120, 130) to the substrate handling chamber, wherein the second processing module is one of a dual chamber module and a quad chamber module.

Step 308 of method 300 further includes controlling the substrate transfer robot assembly to transfer one wafer between the load lock module and the first processing module using the first arm, and to transfer a plurality of wafers simultaneously between the load lock module and the second processing module using the second arm

In exemplary embodiments, method 300 further includes coupling a third processing module to the substrate handling chamber. The second processing module is a dual chamber module (such as module 130) and the third processing module is a quad chamber module (such as module 120). Method 300 further includes controlling the substrate transfer robot assembly to transfer a plurality of wafers simultaneously between the load lock module and the third processing module using the second arm.

In exemplary embodiments, method 300 further includes coupling a fourth processing module to the substrate handling chamber. The fourth processing module is a single chamber module. Method 300 further includes controlling the substrate transfer robot assembly to transfer a single wafer between the load lock module and the fourth processing module using the first arm.

In exemplary embodiments, method 300 further includes providing a rotatable tower (such as tower 202). The second arm is translatable relative to the rotatable tower and the first arm is rotatable relative to the second arm. Method 300 further includes controlling the rotatable tower to transfer wafers between the load lock module and the first processing module independently of the movement of the second arm. In exemplary embodiments of method 300, the first end effector is translatable relative to the second arm, and the second and the third end effector is translatable relative to the first arm.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate transfer robot assembly, comprising:
a tower defining a tower axis;
a first arm and a second arm extending radially outward from the tower;
a first end effector coupled to the tower by the first arm; and
a second end effector and a third end effector coupled to tower by the second arm,
wherein the first end effector is supported by the first arm for translation from the tower radially relative to the tower axis, and
wherein the second end effector and the third end effector are supported by the second arm for translation from the tower radially relative to the tower axis.

2. The substrate transfer robot assembly of claim 1, wherein one of the first arm and the second arm is supported for pivotable movement relative to the tower and about the tower axis.

3. The substrate transfer robot assembly of claim 1, wherein one of the first arm and the second arm is pivotably fixed relative to the tower and about the tower axis.

4. The substrate transfer robot assembly of claim 1, wherein the first arm couples one and only one end effector to the tower.

5. The substrate transfer robot assembly of claim 1, wherein the third end effector is fixed relative to the second end effector and configured for translation in tandem with the second end effector radially from the tower and relative to the tower axis.

6. The substrate transfer robot assembly of claim 1, wherein one of the first arm and the second arm is supported for pivotable movement relative to the tower and about the tower axis, wherein the other of the first arm and the second arm is pivotably fixed relative to the tower and about the tower axis, wherein the first arm couples one and only one end effector to the tower, and wherein the third end effector is fixed relative to the second end effector and configured for translation in tandem with the second end effector radially from the tower and relative to the tower axis.

7. A substrate processing system, comprising:
a substrate handling chamber;
a substrate transfer robot assembly as recited in claim 1, wherein the tower of the substrate transfer robot assembly is supported in the substrate handling chamber for rotation about the tower axis;
a first processing module coupled to the substrate handling chamber;
a second processing module coupled to the substrate handling chamber, the second processing module configured to process a greater number of substrates than the first processing module; and
a controller operatively connected to the substrate transfer robot assembly and responsive to instructions recorded on a memory to:
transfer a single substrate into the first processing module using the first end effector, and
simultaneously transfer two substrates into the second processing module using the second end effector and the third end effector.

8. The substrate processing system of claim 7, wherein the first processing module is a single chamber module, and wherein the second processing module is a dual chamber module or a quad chamber module.

9. The substrate processing system of claim 7, further comprising a third processing module, wherein the second processing module is a dual chamber module, wherein the third processing module is a quad chamber module, and wherein the instructions further cause the controller to simultaneously transfer two substrates into the third processing module using the second end effector and the third end effector.

10. The substrate processing system of claim 9, further comprising:
a singular gate valve coupling the substrate handling chamber to the first processing module;
a first gate valve pair coupling the substrate handling chamber to the second processing module; and
a second gate valve pair coupling the substrate handling chamber to the third processing module.

11. The substrate processing system of claim 9, further comprising a fourth processing module, the fourth processing module being a single chamber module, and wherein the instructions further cause the controller to transfer a single substrate into the fourth processing module using the first end effector.

12. The substrate processing system of claim 7, further comprising:
a load lock module; and
one or more gate valve coupling the substrate handling chamber to the load lock module.

13. The substrate processing system of claim 12, wherein the one or more gate valve is a plurality of gate valves, wherein the instructions cause the controller to open only one of the plurality of gate valve to transfer a single wafer from the load lock module to the first process module, and wherein the instructions cause the controller to open two of the plurality of gate valves to transfer two wafers from the load lock module to the second process module using the second end effector and the third end effector.

14. A method of transferring substrates between a load lock module and a respective processing module, the method comprising:
providing a substrate transfer robot assembly having a first arm and a second arm, wherein the first arm comprises a first end effector, and wherein the second arm comprises a second end effector and a third end effector;
coupling a first processing module to a substrate handling chamber, wherein the first processing module is a single chamber module;
coupling a second processing module to the substrate handling chamber, wherein the second processing module is one of a dual chamber module and a quad chamber module; and
controlling the substrate transfer robot assembly to:
transfer one substrate between the load lock module and the first processing module using the first arm, and
transfer a plurality of substrates simultaneously between the load lock module and the second processing module using the second arm.

15. The method of claim 14, further comprising:
coupling a third processing module to the substrate handling chamber, wherein the second processing module is a dual chamber module and the third processing module is a quad chamber module; and
controlling the substrate transfer robot assembly to transfer a plurality of substrates simultaneously between the load lock module and the third processing module using the second arm.

16. The method of claim 15, further comprising:
coupling a fourth processing module to the substrate handling chamber, wherein the fourth processing module is a single chamber module; and
controlling the substrate transfer robot assembly to transfer a single substrate between the load lock module and the fourth processing module using the first arm.

17. The method of claim 15, further comprising:
providing a rotatable tower comprised in the substrate transfer robot assembly wherein the second arm is translatable relative to the rotatable tower and wherein the first arm is rotatable relative to the second arm; and
controlling the rotatable tower to transfer substrates between the load lock module and the first processing module independently of the movement of the second arm.

18. The method of claim 17, wherein controlling the substrate transfer robot assembly to transfer one substrate between the load lock module and the first processing module using the first arm comprises transferring one and only substrate between the load lock module and the first processing module using a singular end effector coupled to the rotatable tower by the first arm.

19. The method of claim 17, wherein controlling the substrate transfer robot assembly to controlling the substrate transfer robot assembly to transfer a plurality of substrates simultaneously between the load lock module and the second processing module using the second arm further comprises simultaneously transferring two substrates using a second end effector and a second end effector coupled to the rotatable tower by the second arm.

20. The method of claim 19, wherein the third end effector is fixed relative to the second end effector, and wherein the two substrates each comprise a singular wafer.
